(19) United States
(12) Patent Application Publication
(10) Pub. No.: US 2008/0203569 A1
(43) Pub. Date: Aug. 28, 2008

(54) Semiconductor device and manufacturing method thereof

(75) Inventor: Tsutomu Miyamoto, Tokyo (JP)

Correspondence Address: FRISHAUF, HOLTZ, GOODMAN & CHICK, PC, 220 Fifth Avenue, 16TH Floor, NEW YORK, NY, 10001-7708, US

(73) Assignee: Casio Computer Co., Ltd., Tokyo (JP)

(21) Appl. No.: 12/072,833

(22) Filed: Feb. 28, 2008

(30) Foreign Application Priority Data
Feb. 28, 2007 (JP) 2007-050001

(51) Int. Cl. H01L 23/488; H01L 21/44

(52) U.S. Cl. 257/738; 438/614; 257/E23.023; 257/E21.476

(57) ABSTRACT

A semiconductor device comprising: a semiconductor substrate which has a plurality of connection pads on a top surface thereof; an insulating film which is provided on the semiconductor substrate and which has a plurality of openings formed at portions corresponding to the connection pads; a plurality of re-wirings each of which is provided to be connected to one of the connection pads via one of the openings of the insulating film; a re-wiring upper layer insulating film which is filled between the re-wirings on a top surface of the insulating film, and which is provided such that a top surface thereof is as high as or higher than a top surface of the re-wirings; and a plurality of columnar electrodes each of which is provided to be connected to a top surface-side connection pad section of each of the re-wirings.

### BACKGROUND OF THE INVENTION

1. Field of the Invention

The present invention relates to a semiconductor device and a manufacturing method thereof.

2. Description of the Related Art

In some conventional semiconductor devices referred to as chip size package (CPS), for example, a columnar electrode is formed on the top surface of a connection pad section for wirings which has been formed on a semiconductor substrate, as disclosed in Japanese Patent Application KOKAI Publication No. 2004-281614. In this case, the following method is used for manufacturing such semiconductor devices. A plating resist film which includes an opening in the connection pad section for the wiring, that is, at a portion corresponding to a columnar electrode formation region, on the top surface of the wirings formed on an underlying metal layer which has been formed on the entire surface of the semiconductor substrate, and on the top surface of the underlying metal layer. Electrolytic plating is carried out using the underlying metal layer as plating current path, whereby a columnar electrode is formed on the top surface of the connection pad section for the wiring in the opening of the plating resist film. The plating resist film is removed using resist stripping solution. Finally, a region except the region below the wiring of the underlying metal layer is removed by etching, using the wiring as mask.

However, in the above-described conventional method of manufacturing a semiconductor device, when the plating resist film for columnar electrode formation is removed using resist stripping solution, the plating resist film for columnar electrode formation is removed substantially only on the top surface side thereof. Therefore, in the case where the space between the wirings is smaller, resist residue can be generated between the wirings. Particularly between the wirings, since the underlying metal layer is formed such that it is lower than the top surface of the wiring, resist stripping solution is difficult to flow between the wirings, and thus resist residue is likely to be generated. This phenomenon is prominent when a negative-type dry film resist which has strong adhesiveness is used as plating resist film for columnar electrode formation. When the underlying metal layer is etched using the wiring as mask, the resist residue functions as mask and thus causes poor etching since, leading to short circuit.

### SUMMARY OF THE INVENTION

According to the present invention, a re-wiring is formed in an opening of a re-wiring upper layer insulating film such that the top surface thereof is flush with or lower than the top surface of the re-wiring upper layer insulating film, and a plating resist film for columnar electrode formation is formed on the re-wiring. Therefore, there is no room for the plating resist film for columnar electrode formation to enter between the re-wirings. Consequently, the present invention can suppress generation of resist residue when the plating resist film for columnar electrode formation is removed.

A semiconductor device of the present invention comprises:

a semiconductor substrate which has a plurality of connection pads on a top surface thereof;

an insulating film which is provided on the semiconductor substrate and which has a plurality of openings formed at portions corresponding to the connection pads;

a plurality of re-wirings each of which is provided to be connected to one of the connection pads via one of the openings of the insulating film;

a re-wiring upper layer insulating film which is filled between the re-wirings on a top surface of the insulating film, and which is provided such that a top surface thereof is as high as or higher than a top surface of the re-wirings; and

a plurality of columnar electrodes each of which is provided to be connected to a top surface-side connection pad section of each of the re-wirings.

Another semiconductor device of the present invention comprises:

a semiconductor substrate which has a plurality of connection pads on a top surface thereof;

an insulating film which is provided on the semiconductor substrate and which has a plurality of openings formed at portions corresponding to the connection pads;

a plurality of bottom surface-side wirings each of which is provided to be connected to one of the connection pads via one of the openings of the insulating film;

a bottom surface-side upper layer insulating film which is filled between the bottom surface-side wirings on a top surface of the insulating film,

a plurality of re-wirings each of which is provided to be connected to a bottom surface-side connection pad section of each of the bottom surface-side wirings;

a re-wiring upper layer insulating film which is filled between the re-wirings on a top surface of the bottom surface-side upper layer insulating film and on top surfaces of the bottom surface-side wirings, and which is provided such that a top surface thereof is as high as or higher than a top surface of the re-wirings; and

a plurality of columnar electrodes each of which is provided to connect to a top surface-side connection pad section of each of the re-wirings.

A method of manufacturing a semiconductor device of the present invention comprises:

forming, on a semiconductor substrate which has a plurality of connection pads on a top surface thereof, an insulating film having a plurality of openings at portions corresponding to the connection pads;

forming, on a top surface of the insulating film, a re-wiring upper layer insulating film having a plurality of top surface-side openings each of which communicates with each of the openings;

forming, in the top surface-side openings of the re-wiring upper layer insulating film, a metal layer to serve as a plurality of re-wirings such that a top surface thereof is as high as or lower than a top surface of the re-wiring upper layer insulating film;

forming, on the top surface of the metal layer, a plating resist film for columnar electrode formation which has a plurality of openings for columnar electrode at portions to serve as top surface-side connection pad sections of the re-wirings;

forming a plurality of columnar electrodes on top surfaces of the top surface-side connection pad sections of the re-wirings in the openings of the plating resist film for columnar electrode formation;

delaminating the plating resist film for columnar electrode formation; and

forming the re-wirings by etching the metal layer to remove at least portions which are formed on the re-wiring upper layer insulating film.

Another method of manufacturing a semiconductor device of the present invention comprises:

forming, on a semiconductor substrate which has a plurality of connection pads on a top surface thereof, an insulating film having a plurality of openings at portions corresponding to the connection pads;

forming, on a top surface of the insulating film, a bottom surface-side upper layer insulating film having a plurality of bottom surface-side openings each of which communicates with each of the openings;

forming, in the bottom surface-side openings of the bottom surface-side upper layer insulating film, a plurality of bottom surface-side wirings such that a top surface thereof is as high as or lower than a top surface of the bottom surface-side upper layer insulating film;

forming, on the top surface of the bottom surface-side upper layer insulating film and on top surfaces of the bottom surface-side wirings, a re-wiring upper layer insulating film having a plurality of top surface-side openings each of which communicates with each of the bottom surface-side openings;

forming, in the top surface-side openings of the re-wiring upper layer insulating film, a metal layer to serve as a plurality of re-wirings such that a top surface thereof is as high as or lower than a top surface of the re-wiring upper layer insulating film;

forming, on the top surface of the metal layer, a plating resist film for columnar electrode formation which has a plurality of openings for columnar electrode at portions to serve as top surface-side connection pad sections of the re-wirings;

forming a plurality of columnar electrodes on top surfaces of the top surface-side connection pad sections of the re-wirings in the openings of the plating resist film for columnar electrode formation;

delaminating the plating resist film for columnar electrode formation; and forming the re-wirings by etching the metal layer to remove at least portions which are formed on the re-wiring upper layer insulating film.

Still another method of manufacturing a semiconductor device of the present invention comprises:

forming, on a semiconductor substrate which has a plurality of connection pads on a top surface thereof, an insulating film having a plurality of openings at portions corresponding to the connection pads;

forming, on a top surface of the insulating film, a bottom surface-side upper layer insulating film having a plurality of bottom surface-side openings each of which communicates with each of the openings;

forming, in the bottom surface-side openings of the bottom surface-side upper layer insulating film, a plurality of bottom surface-side wirings such that a top surface thereof is as high as or lower than a top surface of the bottom surface-side upper layer insulating film;

forming, on the top surface of the bottom surface-side upper layer insulating film and on top surfaces of the bottom surface-side wirings, a re-wiring upper layer insulating film having a plurality of top surface-side openings each of which communicates with each of the bottom surface-side openings;

forming, in the top surface-side openings of the re-wiring upper layer insulating film, a metal layer to serve as a plurality of re-wirings such that a top surface thereof is as high as or lower than a top surface of the re-wiring upper layer insulating film;

forming, on the top surface of the metal layer, a plating resist film for columnar electrode formation made of a dry film which has a plurality of openings for columnar electrodes at portions to serve as top surface-side connection pad sections of the re-wirings;

forming a plurality of columnar electrodes on top surfaces of the top surface-side connection pad sections of the re-wirings in the openings of the plating resist film for columnar electrode formation;

delaminating the plating resist film for columnar electrode formation; and

forming the re-wirings by etching the metal layer to remove at least portions which are formed on the re-wiring upper layer insulating film.

### BRIEF DESCRIPTION OF THE DRAWINGS

These objects and other objects and advantages of the present invention will become more apparent upon reading of the following detailed description and the accompanying drawings in which:

FIG. 1 is a sectional view of a semiconductor device as a first embodiment of the present invention;

FIG. 2 is a sectional view of a substance which is initially prepared in one example of a method of manufacturing the semiconductor device as shown in FIG. 1;

FIG. 3 is a sectional view of a process subsequent to the process in FIG. 2;

FIG. 4 is a sectional view of a process subsequent to the process of FIG. 3;

FIG. 5 is a sectional view of a process subsequent to the process of FIG. 4;

FIG. 6 is a sectional view of a process subsequent to the process of FIG. 5;

FIG. 7 is a sectional view of a process subsequent to the process of FIG. 6;

FIG. 8 is a sectional view of a process subsequent to the process of FIG. 7;

FIG. 9 is a sectional view of a process subsequent to the process of FIG. 8;

FIG. 10 is a sectional view of a process subsequent to the process of FIG. 9;

FIG. 11 is a sectional view of a process subsequent to the process of FIG. 10;

FIG. 12 is a sectional view of a semiconductor device as a second embodiment of the present invention;

FIG. 13 is a sectional view of a certain process in an example of a method of manufacturing a semiconductor device as shown in FIG. 12;

FIG. 14 is a sectional view of a process subsequent to the process of FIG. 13;

FIG. 15 is a sectional view of a process subsequent to the process of FIG. 14;

FIG. 16 is a sectional view of a process subsequent to the process of FIG. 15;

FIG. 17 is a sectional view of a process subsequent to the process of FIG. 16;

FIG. 18 is a sectional view of a process subsequent to the process of FIG. 17;

FIG. 19 is a sectional view of a process subsequent to the process of FIG. 18; and

FIG. 20 is a sectional view of a semiconductor device as a third embodiment of the present invention.

### DETAILED DESCRIPTION OF THE PREFERRED EMBODIMENTS

Embodiments of the present invention will be explained with reference to the drawings.

### First Embodiment

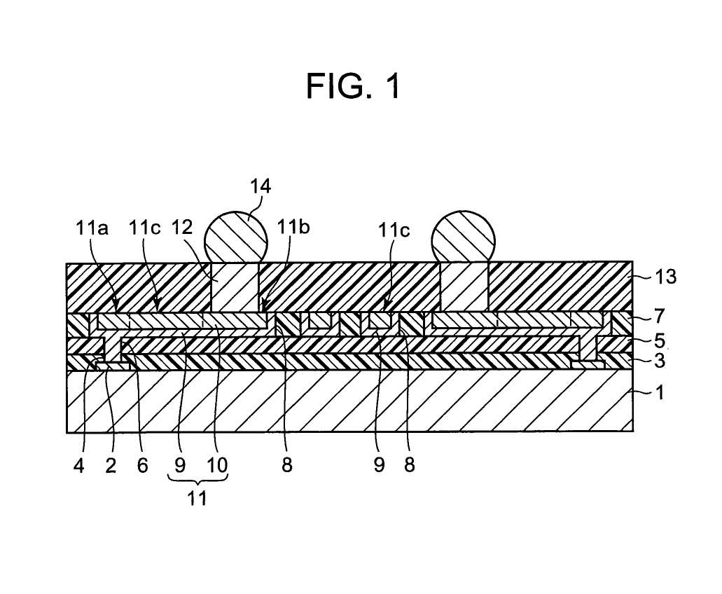

FIG. 1 is a sectional view of a semiconductor device as a first embodiment of the present invention. The semiconductor device, referred to as CPS, includes a silicon substrate (semiconductor substrate) 1. An integrated circuit (which is not shown) is provided on the top surface of the silicon substrate 1, and a plurality of connection pads 2 made of aluminum-series metal or the like are provided in peripheral parts of the top surface such the connection pads 2 they are connected to the integrated circuit.

An insulating film 3 made of oxide silicon or the like is provided on the top surface of the silicon substrate 1 excluding the center parts of the connection pads 2. The center part of each connection pad 2 is exposed via an opening 4 which is provided in the insulating film 3. A protective film (insulating film) 5 made of polyimide-series resin or the like is provided on the top surface of the insulating film 3. An opening 6 is provided in the protective film 5 at a portion corresponding to the opening 4 of the insulating film 3.

An upper layer insulating film (re-wiring upper layer insulating film) 7 made of polyimide-series resin or the like is provided on the top surface of the protective film 5. An opening (top surface-side opening) 8 is provided in each of wiring formation regions (re-wiring formation regions) in the top surface of the upper layer insulating film 7 such that the opening 8 is communicating with the openings 6 of the protective film 5. An underlying metal layer (metal layer) 9 made of cupper or the like is provided in a concave shape on the top surface of the protective film 5 which is exposed via the opening 8 of the upper layer insulating film 7 and on the inner wall surfaces of the opening 8 of the upper layer insulating film 7. An upper metal layer (metal layer) 10 made of cupper is provided inside of the concave-shaped underlying metal layer 9. The underlying metal layer 9 and the upper metal layer 10 are laminated so as to configure a wiring (re-wiring) 11. One end part of the wiring 11 is connected to the connection pad 2 via the openings 4, 6 of the insulating film 3 and of the protective film 5, respectively.

In this case, the top surfaces at both ends of the concave-shaped underlying metal layer 9 which is provided on the inner wall surfaces of the opening 8 of the upper layer insulating film 7 is flush with the top surface of the upper layer insulating film 7. The top surface of the upper metal layer 10 is flush with or slightly lower than the top surface of the upper layer insulating film 7. In addition, one end part of the wiring 11 is referred to as a connecting section 11a which is connected to the connection pad 2, and the other end part thereof is referred to as a connection pad section (top surface-side connection pad section) 11b which is connected to a columnar electrode 12. The wiring 11 further includes a routing line section 11c which connects the connecting section 11a and the connection pad section 11b.

The columnar electrode 12 made of cupper is provided on the top surface of the connection pad section 11b for the wiring 11. A passivation film 13 made of epoxy-series resin or the like is provided on the top surfaces of the wiring 11 and the upper layer insulating film 7, such that the top surface thereof is flush with the top surface of the columnar electrode 12. A solder ball 14 is provided on the top surface of the columnar electrode 12.

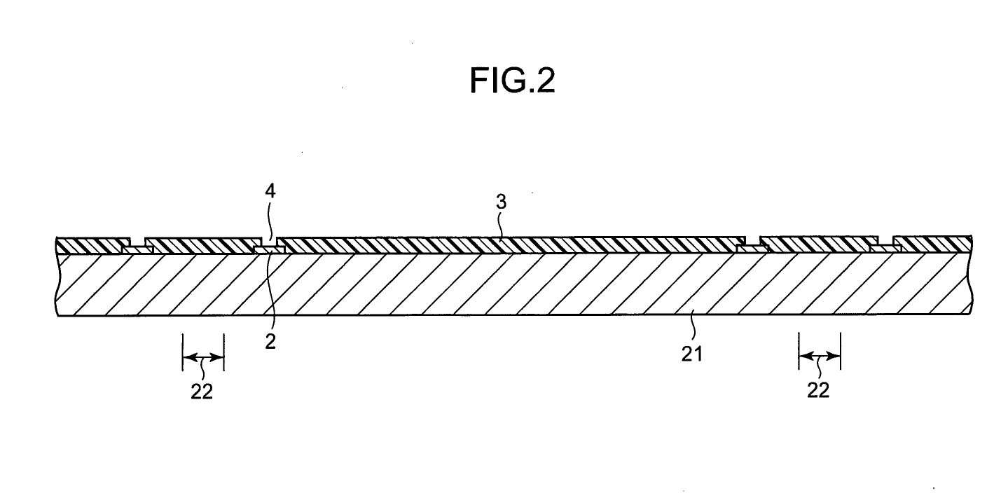

One example of a method of manufacturing the semiconductor device will now be described. As shown in FIG. 2, a substance is first prepared. In the substance, the connection pads 2 made of aluminum-series metal or the like and the insulating films 3 made of oxide silicon or the like have been formed on the top surface of the silicon substrate in the wafer state (hereinafter referred to as a semiconductor wafer 21) and the center part of each connection pad 2 is exposed via the opening 4 formed in the insulating film 3.

In this case, an integrated circuit (which is not shown) having a certain function is formed in each of regions in the top surface of the semiconductor wafer 21 where individual semiconductor devices are formed, and each connection pad 2 is electrically connected to the integrated circuit formed in the corresponding region. Note that, in FIG. 2, the region indicated by Numeral 22 is a region corresponding to the dicing line.

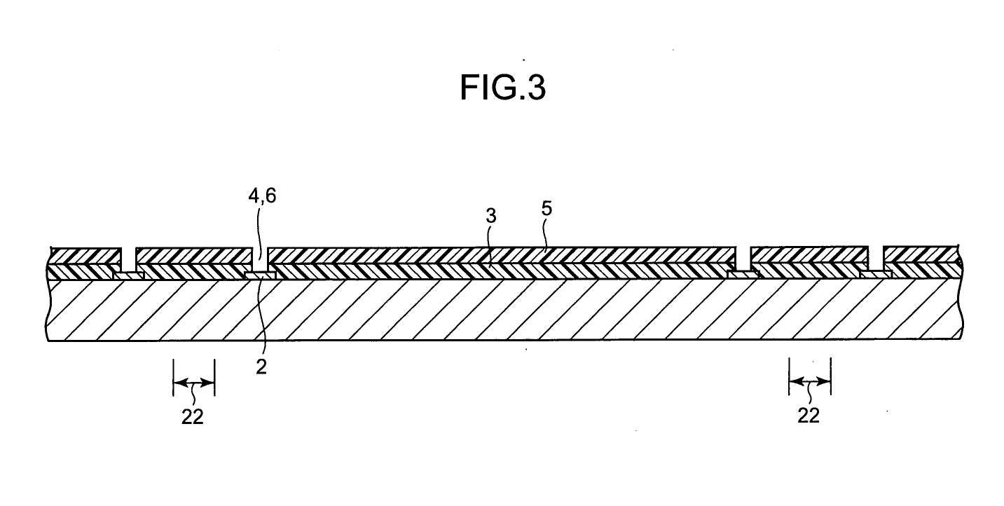

Next, as shown in FIG. 3, the protective film 5 is formed on the top surface of the insulating film 3, by patterning relying upon photolithographic method a film for protective film formation made of polyimide-series resin or the like which has been formed by spin coat method or the like so as to cure it. In this state, the opening 6 is formed in the protective film 5 at a portion corresponding to the opening of the insulating film 3.

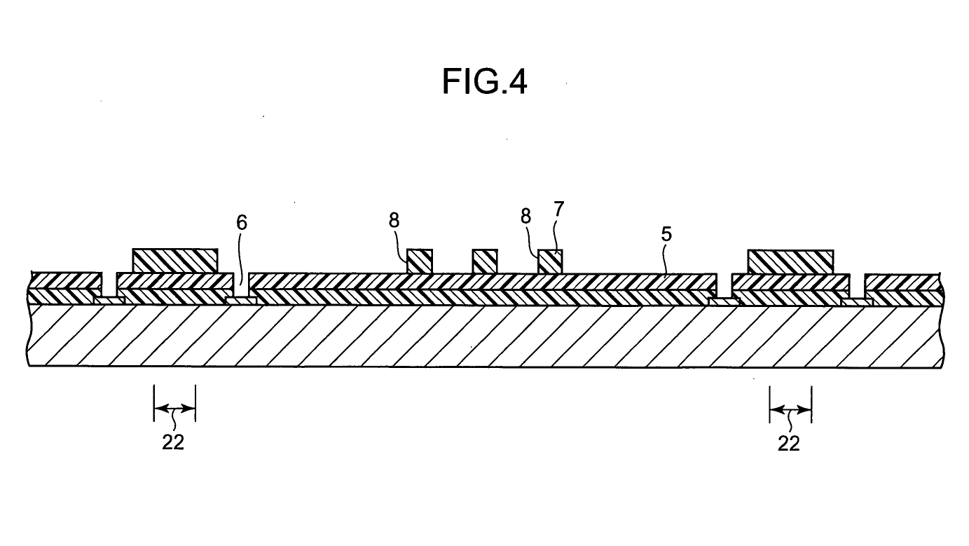

Next, as shown in FIG. 4, the upper layer insulating film 7 is formed on the top surface of the protective film 5, by exposing using exposure mask (which is not shown) a film for upper layer insulating film formation made of photosensitive polyimide-series resin or the like which has been formed by spin coat method or the like, developing it, and curing it. In this state, the opening 8 is formed in the wiring formation region of the upper layer insulating film 7 such that the opening 8 is communicating with the opening 6 of the protective film 5.

In this case, the protective film 5 may be formed of the same material as the upper layer insulating film 7 (for example, negative-type photosensitive polyimide-series resin). In this case, it is possible to expose and develop the film for protective film formation which has been applied, subsequently tentatively curing the film for protective film formation, subsequently applying the film for upper layer insulating film formation, subsequently exposing and developing the film for upper layer insulating film formation, and subsequently carrying out main curing of the film for protective film formation and the film for upper layer insulating film formation.

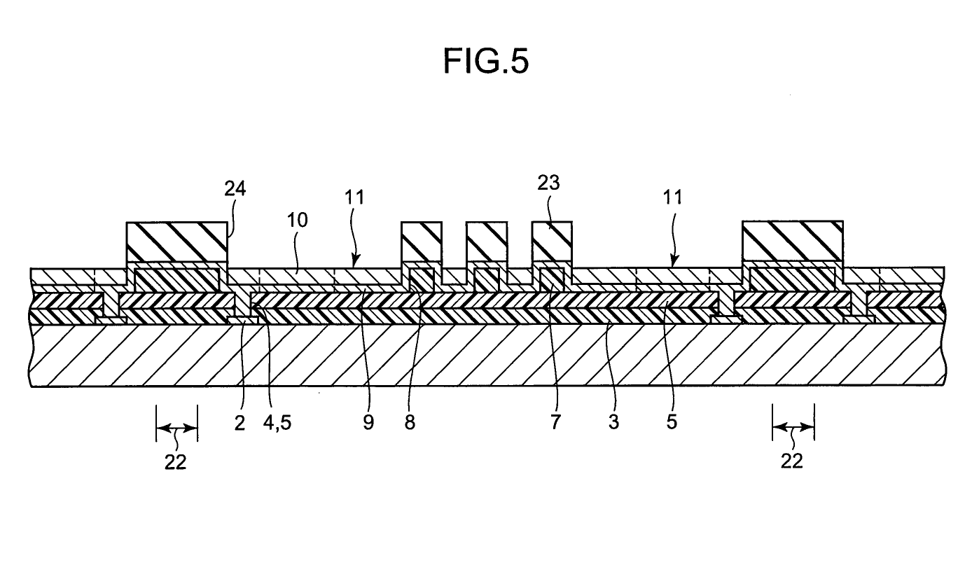

Next, as shown in FIG. 5, the underlying metal layer 9 is formed on the top surface of the connection pad 2 exposed via the openings 4, 6, 8 of the insulating film 3, the protective film 5 and the upper layer insulating film 7, respectively, on the top surface of the protective film 5 exposed via the opening 8 of the upper layer insulating film 7, and on the surface of the upper layer insulating film 7. In this case, the underlying metal layer 9 is formed in a solid plane along the bottom surface of the opening 8 of the upper layer insulating film 7 and along the side surfaces forming the peripheral of the opening 8. The underlying metal layer 9 is formed into a concave shape with the bottom surface section and the side sections. In addition, the underlying metal layer 9 may be a cupper layer formed only by non-electrolytic plating, may be a cupper layer only formed by spattering, or may be a cupper layer formed by spattering on a thin film layer made of titanium or the like which has been formed by spattering.

Next, a plating resist film 23 for wiring formation is formed on the top surface of the underlying metal layer 9, by patterning relying upon photolithographic method a positive-type resist film which has been applied by spin coat method or the like. In this state, an opening (opening for rewiring) 24 is formed on the plating resist film 23 for upper metal layer formation at a portion corresponding to the upper metal layer 10 formation region. In this case, the size of the opening 24 of the plating resist film 23 for upper metal layer formation is smaller than the size of the opening 8 of the upper layer insulating film 7 by the amount equivalent to the film thickness of the underlying metal layer 9.

Next, the upper metal layer 10 is formed inside of the concave-shaped underlying metal layer 9 in the opening 24 of the upper layer insulating film 7, by carrying out electrolytic plating of cupper using the underlying metal layer 9 as plating current path. The top surface of the upper metal layer 10 should be flush with or slightly lower than the top surface of the upper layer insulating film 7.

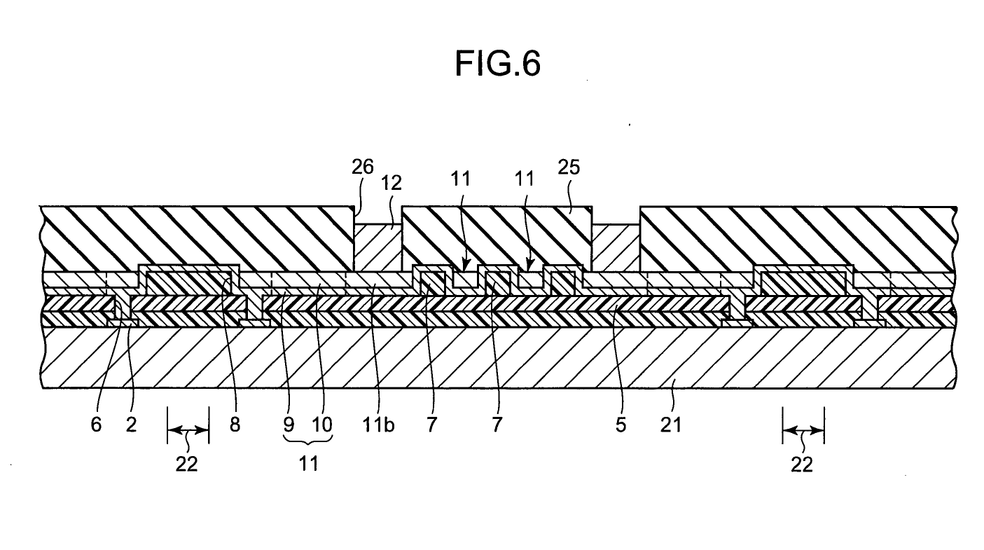

Next, the plating resist film 23 for upper metal layer formation is removed using resist stripping solution. Subsequently, as shown in FIG. 6, a plating resist film for columnar electrode formation 25 is formed on the top surface of the wiring 11, by laminating a negative-type dry film resist, and patterning by photolithographic method the negative-type dry film resist. In this state, an opening (opening for columnar electrode) 26 is formed in the plating resist film for columnar electrode formation 25 at a portion corresponding to the connection pad section 11b for the wiring 11 (columnar electrode 12 formation region).

Next, the columnar electrode 12 is formed on the top surface of the connection pad section 11b for the wiring 11 in the opening 26 of the plating resist film 25 for columnar electrode formation by carrying out electrolytic plating of cupper using the underlying metal layer 9 as plating current path. Next, the plating resist film 25 for columnar electrode formation is removed using resist stripping solution. In this case, the plating resist film 25 for columnar electrode formation swells and thereby is removed from the surface which is in contact with the resist stripping solution.

Conventionally, the underlying metal layer 9 is formed such that it is lower than the top surface of the upper metal layer 10 for the wiring 11 between the wirings 11. Accordingly, resist stripping solution flows between the wirings, and thus resist residue is likely to be generated. Particularly in the case where the space between the wirings 11 is smaller, resist residue is more likely to be generated. On the other hand, in the first embodiment, the plating resist film 25 for columnar electrode formation between the wirings 11 is formed at a position slightly higher than the top surface of the upper metal layer 10 for the wiring 11. In this case, resist stripping solution is likely to be in contact with the plating resist film 25 for columnar electrode formation between the wirings 11. Therefore, the plating resist film 25 for columnar electrode formation is favorably removed by resist stripping solution, and therefore, resist residue of the plating resist film 25 is not generated. In addition, in the state where the plating resist film 25 for columnar electrode formation is formed, the upper layer insulating film 7 exists between the wirings each of which having the laminated structure comprising the underlying metal layer 9 and of the upper metal layer 10. Therefore, there is no room for the plating resist film 25 for columnar electrode formation to enter between the wirings 11. Accordingly, even in the case where the space between the wirings 11 becomes smaller, insulation between the wirings 11 is ensured.

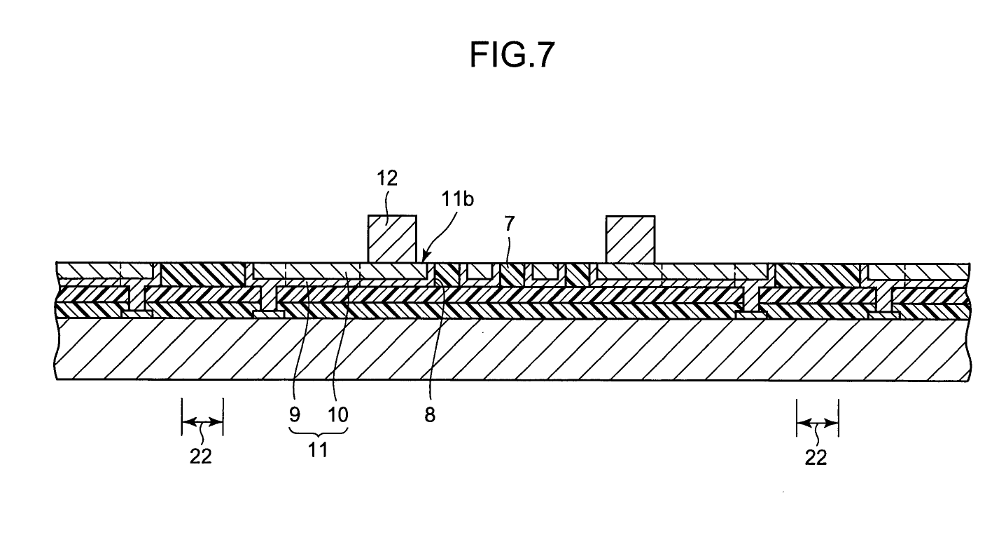

In this way, the plating resist film 25 for columnar electrode formation is removed using resist stripping solution, and then the underlying metal layer 9 which is exposed at a position higher than the top surface of the upper layer insulating film 7 is removed by etching. As a result of this, the underlying metal layer 9 remains only in the opening 8 of the upper layer insulating film 7 as shown in FIG. 7. This leads to formation of the wiring 11, as illustrated in FIG. 1, which has the laminated structure comprising the underlying metal layer 9 and the upper metal layer 10 and which includes the connecting section 11a connected to the connection pad 2, the connection pad section 11b at the distal end and the routing line section 11c therebetween.

In this case, as described above, resist residue of the plating resist film 25 for columnar electrode formation is not generated on the top surface of the underlying metal layer 9 between the wirings 11. In addition, since the underlying metal layer 9 is formed on the top surface of the upper layer insulating film 7 between the wirings 11, the underlying metal layer 9 is flush with or slightly higher than the top surface of the upper metal layer 10 for the wiring 11. Accordingly, resist stripping solution is likely to be in contact with the surface of the underlying metal layer 9 between the wirings 11. Therefore, the underlying metal layer 9 can be removed reliably by etching, and consequently, insulation between the wirings 11 can be ensured.

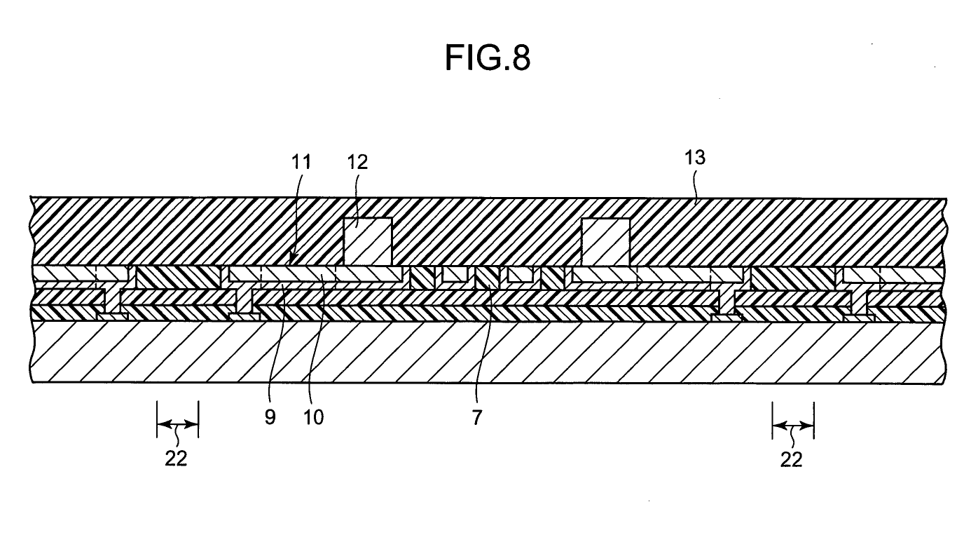

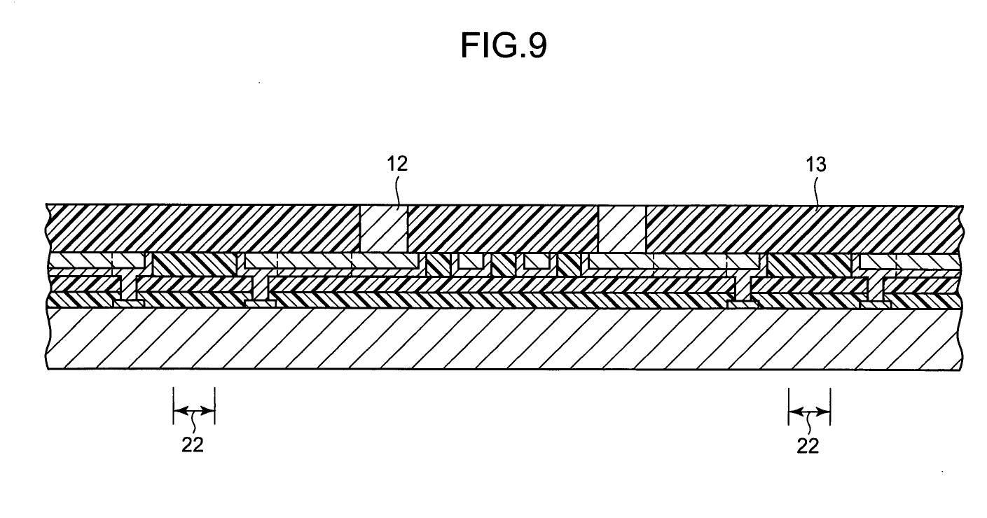

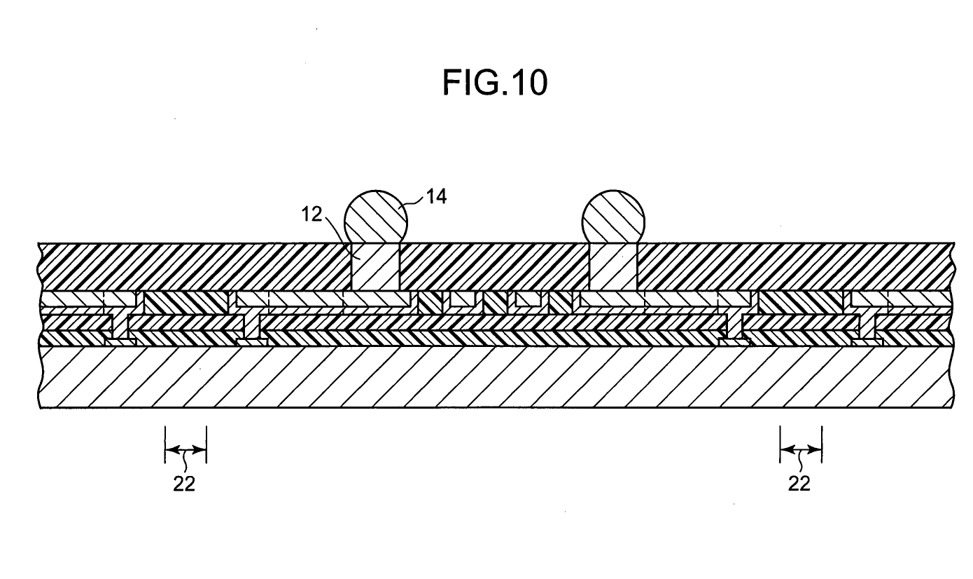

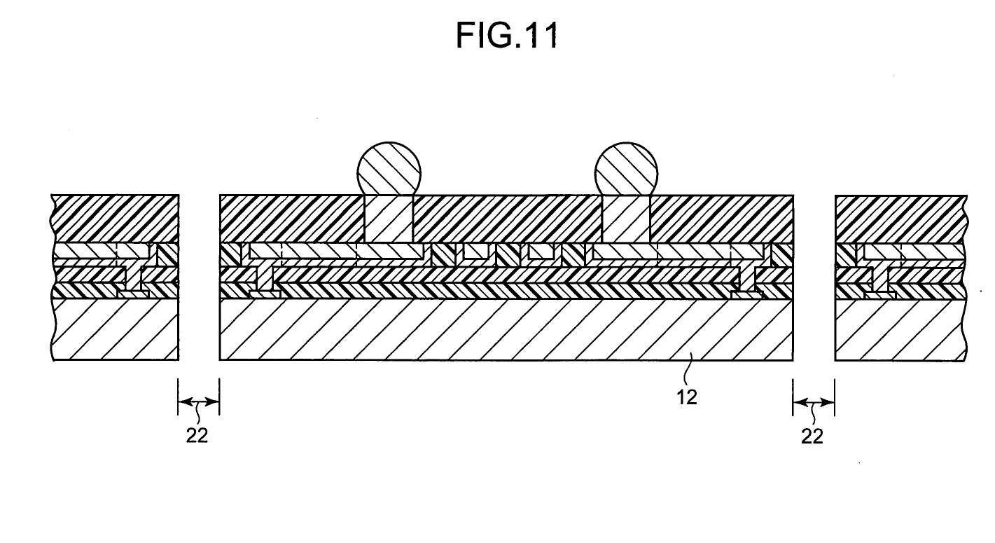

Next, as shown in FIG. 8, the passivation film 13 made of epoxy-series resin or the like is formed on the top surface of the upper layer insulating film 7 including the wiring 11, the underlying metal layer 9 and the columnar electrode 12 such that thickness of the passivation film 13 is slightly larger than the height of the columnar electrode 12. In this state, accordingly, the top surface of the columnar electrode 12 is covered with the passivation film 13. Next, the top surface-side of the passivation film 13 is ground as appropriately, whereby, as shown in FIG. 9, the top surface of the columnar electrode 12 is exposed, and the top surface of the passivation film 13 including the exposed top surface of the columnar electrode 12 is made flat. Next, as shown in FIG. 10, the solder ball 14 is formed on the top surface of the columnar electrode 12. Next, as shown in FIG. 11, the semiconductor wafer 21 or the like is cut along the dicing line 22, whereby a plurality of semiconductor devices as shown in FIG. 1 are obtained.

### Second Embodiment

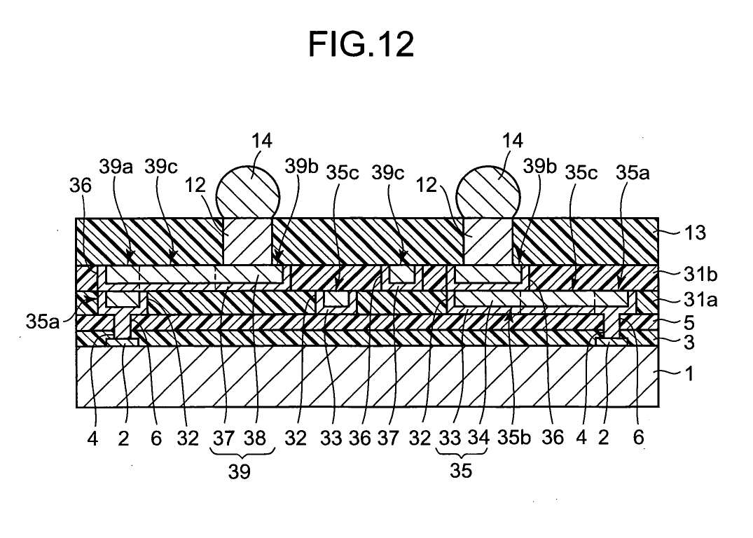

FIG. 12 is a sectional view of a semiconductor device as a second embodiment of the present invention. The semiconductor device differs from the semiconductor device as shown in FIG. 1 in the fact that the wiring and the upper layer insulating film have 2 layers, respectively. Specifically, a first upper layer insulating film (bottom surface-side upper layer insulating film) 31a made of polyimide-series resin or the like is provided on the top surface of the protective film 5. An opening (bottom surface-side openings) 32 is provided in the first wiring formation region in the top surface of the first upper layer insulating film 31a such that the opening 32 is communicating with the opening 6 of the protective film 5.

A first underlying metal layer (metal layer) 33 made of cupper or the like is provided in a concave shape on the top surface of the protective film 5 which is exposed via the opening 32 of the first upper layer insulating film 31a and on the inner wall surfaces of the opening 32 of the first upper layer insulating film 31a. A first upper metal layer (metal layer) 34 made of cupper is provided inside of the concave-shaped first underlying metal layer 33. The first underlying metal layer 33 and the first upper metal layer 34 are laminated so as to configure a first wiring 35 (bottom surface-side wiring). One end part of the first wiring 35 is connected to the connection pad 2 via the openings 4, 6 of the insulating film 3 and of the protective film 5, respectively.

Also in this case, the top surface of the first underlying metal layer 33 which is provided on the inner wall surfaces of the opening 32 of the first upper layer insulating film 31a is flush with the top surface of the first upper layer insulating film 31a. The top surface of the first upper metal layer 34 is flush with or slightly lower than the top surface of the first upper layer insulating film 31a. In addition, one end part of the first wiring 35 is referred to as a connecting section (bottom surface-side connecting section) 35a which is connected to the connection pad 2, and the other end part thereof is referred to as a connection pad section (bottom surface-side connection pad section) 35b which is connected to a connecting section 39a for the second wiring 35. The wiring 35 further includes a routing line section 35c which connects the connecting section 35a and the connection pad section 35b.

In this case, the one end parts of all first wirings 35 (connecting sections 35a) are connected to the connection pads 2 via the openings 4, 6 of the insulating film 3 and of the protective film 5, respectively. However, some of the first wirings 35 comprises only the connecting sections 35a. In this case, the connecting section 35a of each first wiring 35 is connected to the connecting section 39a for the second wiring 39. Accordingly, the number of the routing line sections 35c for the first wiring 35 is smaller than the number of the routing line sections 11b for the wiring 11 as shown in FIG. 1.

A second upper layer insulating film (re-wiring upper layer insulating film) 31b made of polyimide-series resin or the like is provided on the top surface of the first wiring 35 and the first upper layer insulating film 31a. An opening (top surface-side opening) 36 is provided in a second wiring formation region on the top surface of the second upper layer insulating film 31b. In this case, some of the openings 36 are provided only in regions corresponding to the connection pad sections 35b for the first wirings 35.

A second underlying metal layer 37 made of cupper or the like is provided in a concave shape on the top surface of the first upper layer insulating film 31a exposed via the opening 36 of the second upper layer insulating film 31b and on the inner wall surfaces of the opening 36 of the second upper layer insulating film 31b. A second upper metal layer 38 made of cupper is provided inside of the concave-shaped second underlying metal layer 37. The second underlying metal layer 37 and the second upper metal layer 38 are laminated so as to configure the second wiring (re-wiring) 39.

Also in this case, the top surface of the second underlying metal layer 37 which is provided on the inner wall surfaces of the opening 36 of the second upper layer insulating film 31b is flush with the top surface of the second upper layer insulating film 31b. The top surface of the second upper metal layer 38 is flush with or slightly lower than the top surface of the second upper layer insulating film 31b. In addition, one end part of the second wiring 39 is referred to as the connecting section (top surface-side connecting section) 39a which is connected to the connection pad section 35b of the first wiring 35, and the other end part thereof is referred to as a connection pad section (top surface-side connection pad section) 39b which is connected to the columnar electrode 12. The wiring 39 further includes a routing line section 39c which connects the connecting section 39a and the connection pad section 39b.

In addition, one end parts (connecting sections 39a) of some of the second wirings 39 are connected to the top surface of the first wiring 35 comprising only the connecting section 35a. The rest of the second wirings 39, formed in an island shape, consist only of the connection pad section 39b, and are provided only on the top surface of the connection pad section 35b for the first wiring 35. In this case, the connection pad section 35b for the second wiring 39 is connected to the connecting section 35a for the first wiring 35. In this case, the total number of the routing line sections 35c, 39c for the first and second wirings 35, 39 is the same as the number of the routing line section 11b of the wiring 11 as shown in FIG. 1.

The columnar electrode 12 made of cupper is provided on the top surface of the connection pad section 39b of the second wiring 39. The passivation film 13 made of epoxy-series resin or the like is provided on the top surfaces of the second wiring 39 and the second upper layer insulating film 31b such that the top surface of the passivation film 13 is flush with the top surface of the columnar electrode 12. The solder ball 14 is provided on the top surface of the columnar electrode 12.

In the semiconductor device, some of the first wirings 35 consist only of the connecting sections 35a, and some of the second wirings 39 consist only of the connection pad sections 39b. In addition, the total number of the routing line sections 35c, 39c for the first and second wirings 35, 39, respectively, is the same as the number of the routing line sections 11b for the wiring 11. Therefore, degree of freedom in routing of the routing line sections 35c, 39c for the first and second the second wirings 35, 39 can be enhanced compared to the case of the semiconductor device as shown in FIG. 1.

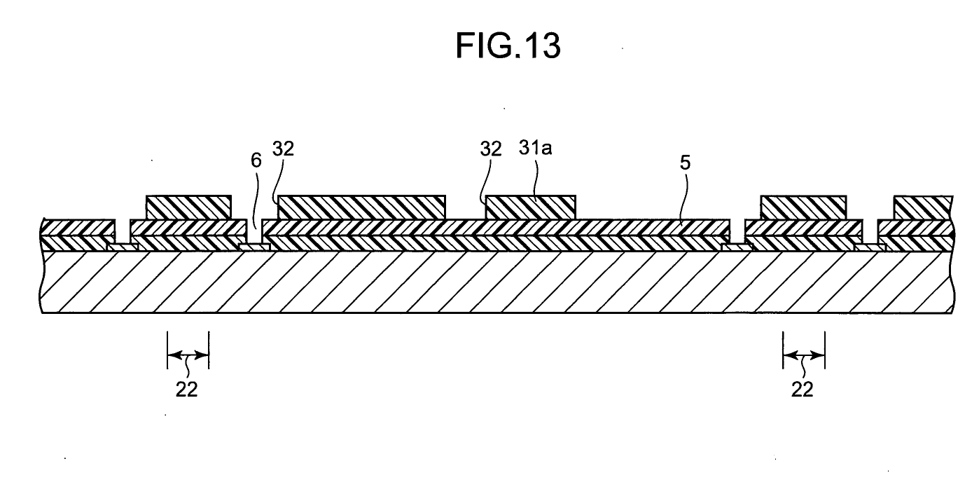

An example of a method of manufacturing the semiconductor device will now be described. In this case, subsequent to the process as shown in FIG. 3, the first upper layer insulating film 31a is formed on the top surface of the protective film 5, by patterning relying upon photolithographic method a film for first upper layer insulating film formation which is made of polyimide-series resin or the like and which has been formed by spin coat method or the like, as shown in FIG. 13. In this state, the opening 32 is formed in the first wiring formation region of the first upper layer insulating film 3 a such that the opening 32 is communicating with the opening 6 of the protective film 5.

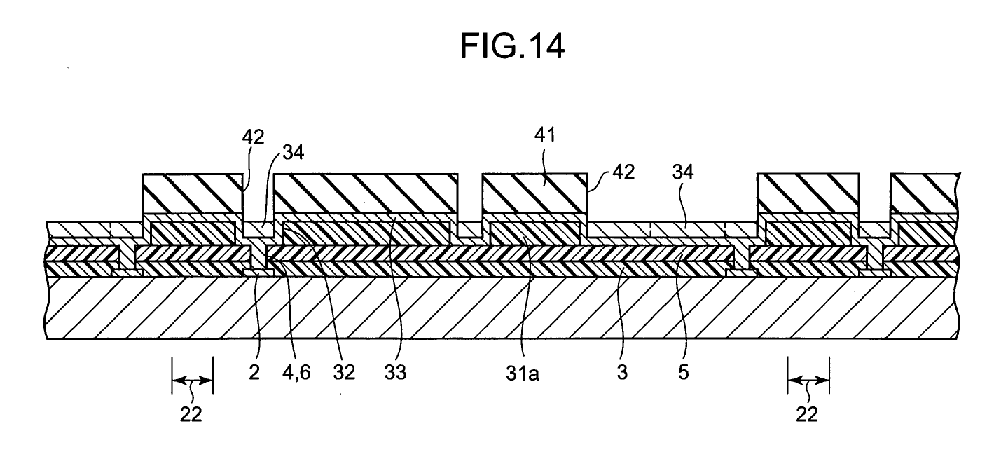

Next, as shown in FIG. 14, the first underlying metal layer 33 made of cupper or the like is formed by spattering method or the like on the top surface of the connection pad 2 which is exposed via the openings 4, 6, 32 of the insulating film 3, the protective film 5 and the first upper layer insulating film 31a, respectively, on the top surface of the protective film 5 which is exposed via the opening 32 of the first upper layer insulating film 31a and on the surface of the first upper layer insulating film 31a. In this case, the first underlying metal layer 33 formed inside of the opening 32 of the first upper layer insulating film 31a is formed into a concave shape.

Next, a plating resist film 41 for first upper metal layer formation is formed on the top surface of the first underlying metal layer 33, by patterning relying upon photolithographic method a positive-type resist film which has been applied by spin coat method or the like. In this state, an opening (opening for rewiring) 44 is formed in the plating resist film 41 for first upper metal layer formation at a portion corresponding to the first upper metal layer formation region. Also in this case, the size of the opening 42 of the plating resist film 41 for first upper metal layer formation is smaller than the size of the opening 32 of the first upper layer insulating film 31a by the amount equivalent to the film thickness of the first underlying metal layer 33.

Next, the first upper metal layer 34 is formed inside of the concave-shaped first underlying metal layer 33 in the opening 42 of the plating resist film 41 for first upper metal layer formation by carrying out electrolytic plating of cupper using the first underlying metal layer 33 as plating current path. Also in this case, the top surface of the first upper metal layer 34 should be flush with or slightly lower than the top surface of the first upper layer insulating film 31a.

Next, the plating resist film 41 for first upper metal layer formation is removed using resist stripping solution. In this case, as is the case with the first embodiment, the plating resist film 41 for first upper metal layer formation is formed at a position slightly higher than the top surface of the upper metal layer 34 of the first wiring 35 between the first wirings 35. In this case, resist stripping solution is likely to be in contact with the plating resist film 41 for first upper metal layer formation between the first wirings 35. Therefore, the plating resist film 41 for first upper metal layer formation is favorably removed by resist stripping solution, and therefore, resist residue of the plating resist film 25 is not generated. In addition, in the state where the plating resist film 41 for first upper metal layer formation is formed, the first upper layer insulating film 31a exists between the first wirings 35 each of which having the laminated structure comprising the first underlying metal layer 33 and the first upper metal layer 34. Therefore, there is no room for the plating resist film 41 for first upper metal layer formation to enter between the first wirings 35. Accordingly, even in the case where the space between the first wirings 35 becomes smaller, insulation between the first wirings 35 is ensured.

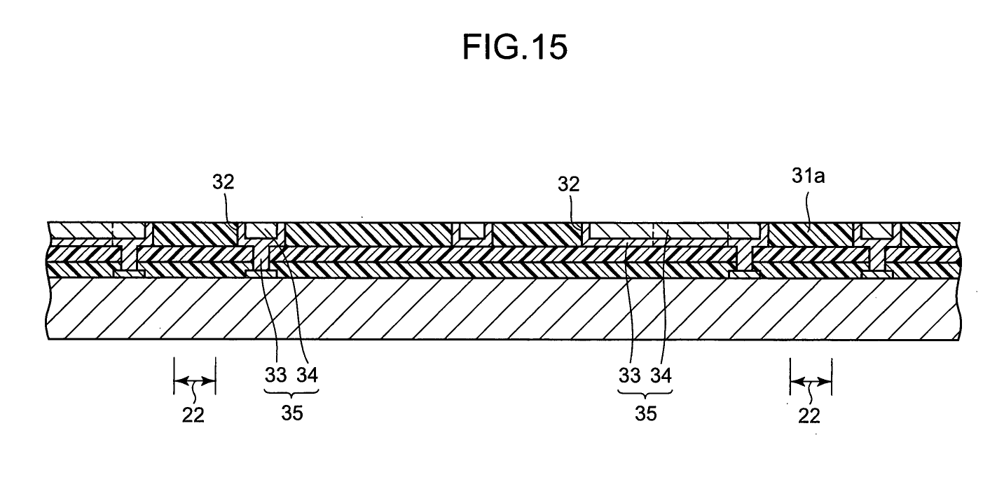

Next, the first underlying metal layer 33 which is exposed at a position higher than the top surface of the first upper layer insulating film 31a is removed by etching. As a result of this, the first underlying metal layer 33 remains only in the opening 32 of the first upper layer insulating film 31a as shown in FIG. 15. In this case, as described above, resist residue of the plating resist film 41 for first upper metal layer formation is not generated on the top surface of the first underlying metal layer 33 between the first wirings 35. In addition, since the underlying metal layer 33 is formed on the top surface of the first upper layer insulating film 31a between the first wirings 35, the underlying metal layer 33 is flush with or slightly higher than the top surface of the first upper metal layer 34 of the first wiring 35. Accordingly, resist stripping solution is likely to be in contact with the surface of the first underlying metal layer 33 between the first wirings 35. Therefore, removal of the first underlying metal layer 33 by etching can be ensured removed, and consequently, insulation between the first wirings 35 can be ensured.

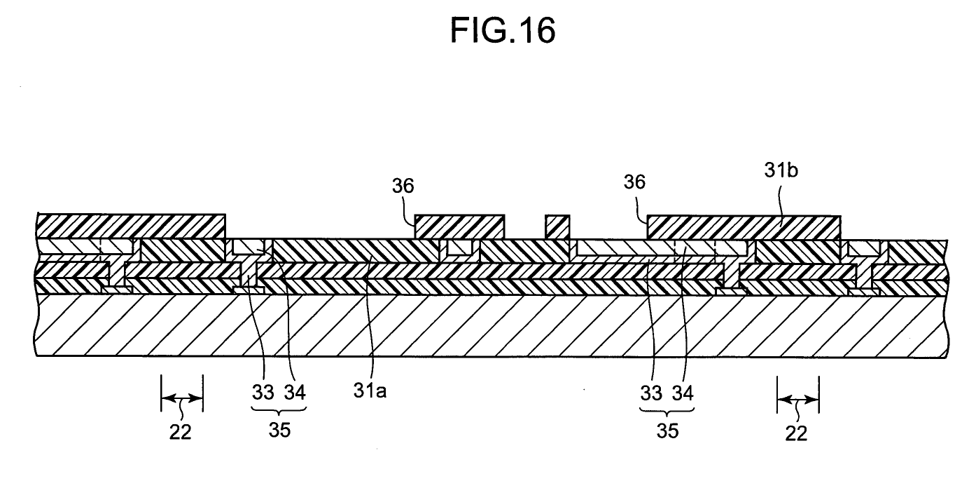

Next, as shown in FIG. 16, the second upper layer insulating film 31b is formed on the top surfaces of the first wiring 35, the first underlying metal layer 33 and the first upper layer insulating film 31a, by patterning relying upon photolithographic method a film for second upper layer insulating film formation made of polyimide-series resin or the like which has been formed by spin coat method or the like. In this state, the opening 36 is formed in the second upper metal layer formation region of the second upper layer insulating film 31b.

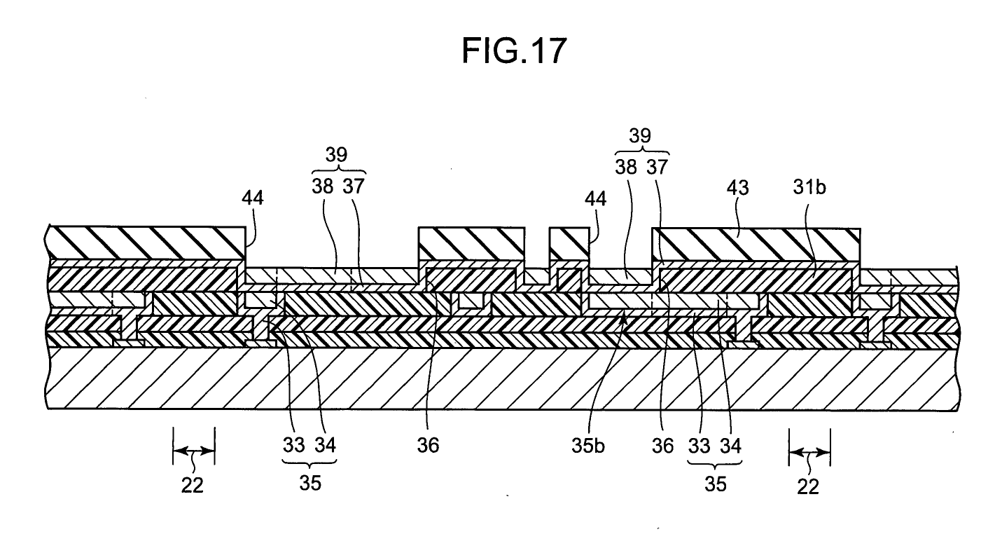

Next, as shown in FIG. 17, the second underlying metal layer 37 made of cupper or the like is formed by spattering method or the like, on the top surface of the first wiring 35 which is exposed via the opening 36 of the second upper layer insulating film 31b and on the surface of the second upper layer insulating film 31b. In this case, the second underlying metal layer 37 formed inside of the opening 36 of the second upper layer insulating film 31b is formed into a concave shape.

Next, on the top surface of the second underlying metal layer 37, a plating resist film for second upper metal layer formation 43 is formed by patterning relying upon photolithographic method a positive-type resist film which has been applied by spin coat method or the like. In this state, an opening 44 is formed in the plating resist film for second upper metal layer formation 43 at a portion corresponding to the second upper metal layer formation region. Also in this case, the size of the opening 44 of the plating resist film for second upper metal layer formation 43 is smaller than the size of the opening 36 of the second upper layer insulating film 31b by the amount equivalent to the film thickness of the second underlying metal layer 37.

Next, the second upper metal layer 38 is formed inside of the concave-shaped second underlying metal layer 37 in the opening 44 of the plating resist film for second upper metal layer formation 43 by carrying out electrolytic plating of cupper using the second underlying metal layer 37 as plating current path. Also in this case, the top surface of the second upper metal layer 38 should be flush with or slightly lower than the top surface of the second upper layer insulating film 31b. Next, the plating resist film for second upper metal layer formation 43 is removed using resist stripping solution. Also in this case, resist stripping solution is likely to be in contact with the plating resist film for second upper metal layer formation 43 between the second wirings 39. Therefore, the plating resist film for second upper metal layer formation 43 is favorably removed by resist stripping solution, and therefore, resist residue of the plating resist film for second upper metal layer formation 43 is not generated. In addition, in the state where the plating resist film for second upper metal layer formation 43 is formed, the second upper layer insulating film 31b exists between the second wirings 39 each of which having the laminated structure comprising the second underlying metal layer 37 and the second upper metal layer 38. Therefore, insulation between the second wirings 39 is ensured.

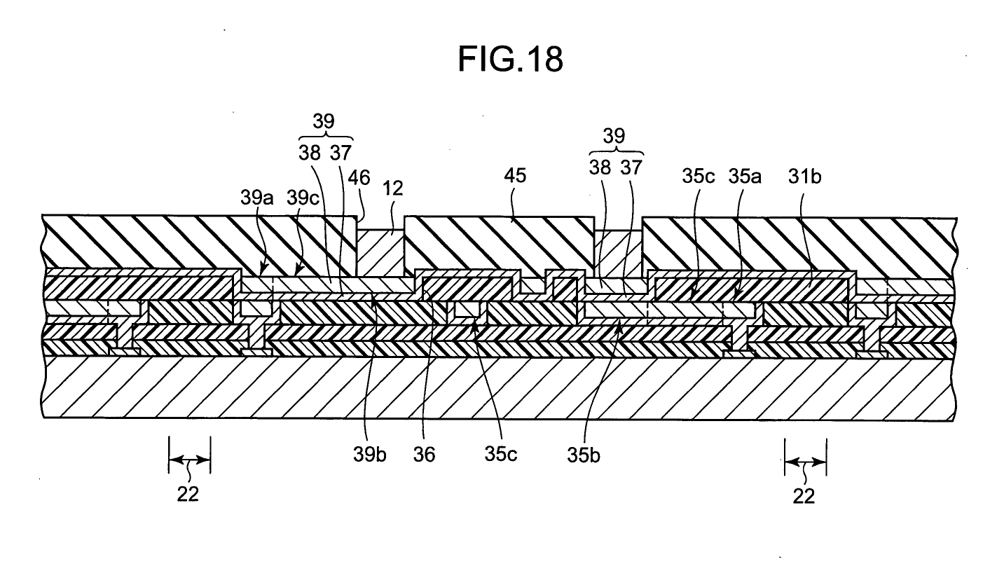

Next, as shown in FIG. 18, the plating resist film 45 for columnar electrode formation is formed by laminating a negative-type dry film resist on the top surfaces of the second upper metal layer 38 and the second underlying metal layer 37, and then patterning by photolithographic method the negative-type dry film resist. In this state, an opening (opening for columnar electrode) 46 is formed in the plating resist film 45 for columnar electrode formation at a portion corresponding to the connection pad section 39b for the second wiring 39 (columnar electrode 12 formation region).

Next, the columnar electrode 12 is formed on the top surface of the connection pad section 39b of the second wiring 39 in the opening 46 of the plating resist film 45 for columnar electrode formation, by carrying out electrolytic plating of cupper using the second underlying metal layer 37 as plating current path. Next, the plating resist film 45 for columnar electrode formation is removed using resist stripping solution. Also in this case, the plating resist film 45 for columnar electrode formation swells and thereby is removed from the surface which is in contact with resist stripping solution.

In this case, as is the case with the first embodiment, the plating resist film 45 for columnar electrode formation is formed at a position slightly higher than the top surface of the second upper metal layer 38 of the second wiring 39 between the second wirings 39. In this case, resist stripping solution is likely to be in contact with the plating resist film 45 for columnar electrode formation between the second wirings 39. Therefore, the plating resist film 45 for columnar electrode formation is favorably removed by resist stripping solution, and therefore, resist residue of the plating resist film 45 for columnar electrode formation is not generated. In addition, in the state where the plating resist film 45 for columnar electrode formation is formed, the second upper layer insulating film 31b exists between the second wirings 39. Therefore, there is no room for the plating resist film 45 for columnar electrode formation to enter between the second wirings 39. Accordingly, even in the case where the space is smaller between the second wirings 39, insulation between the second wirings 39 is ensured.

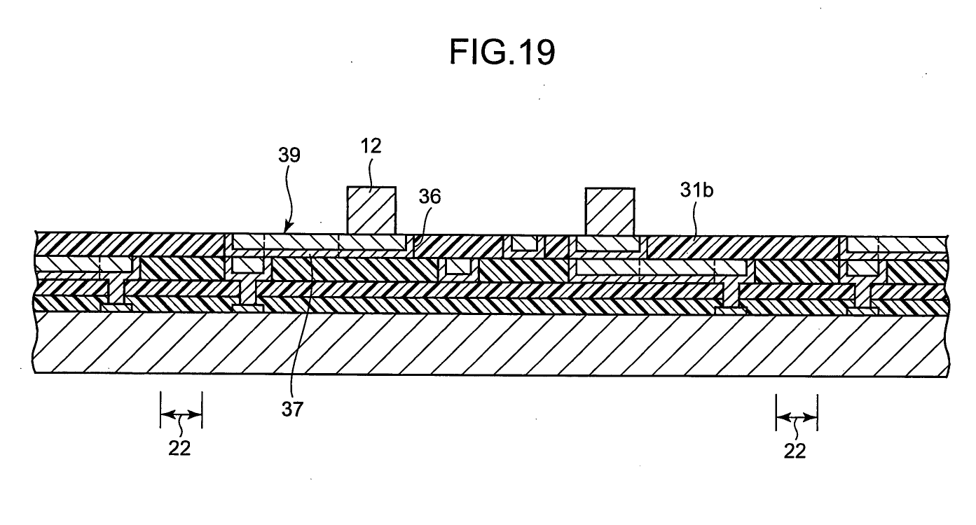

In this way, the plating resist film 45 for columnar electrode formation is removed using resist stripping solution, and then the second underlying metal layer 37 which is exposed at a position higher than the top surface of the second upper layer insulating film 31b is removed by etching. As a result of this, the second underlying metal layer 37 remains only in the opening 36 of the second upper layer insulating film 31b, as shown in FIG. 19. As is the case with the above-described first embodiment, a plurality units of the semiconductor devices as shown in FIG. 12 are obtained after being subjected to the process of forming the passivation film 13, the process of forming the solder ball 14, and the dicing process.

Also in this case, as described above, resist residue of the plating resist film 45 for columnar electrode formation is not generated on the top surface of the second underlying metal layer 37 between the second wirings 39. In addition, since the second underlying metal layer 37 is formed on the top surface of the second upper layer insulating film 31b between the second wirings 39, the second underlying metal layer 37 is flush with or slightly higher than the top surface of the second upper metal layer 38 of the second wiring 39. Accordingly, since resist stripping solution is likely to be in contact with the surface of the second underlying metal layer 37 between the second wirings 39, removal of the second underlying metal layer 37 can be ensured by etching, and consequently, insulation between the second wirings 39 can be ensured.

### Third Embodiment

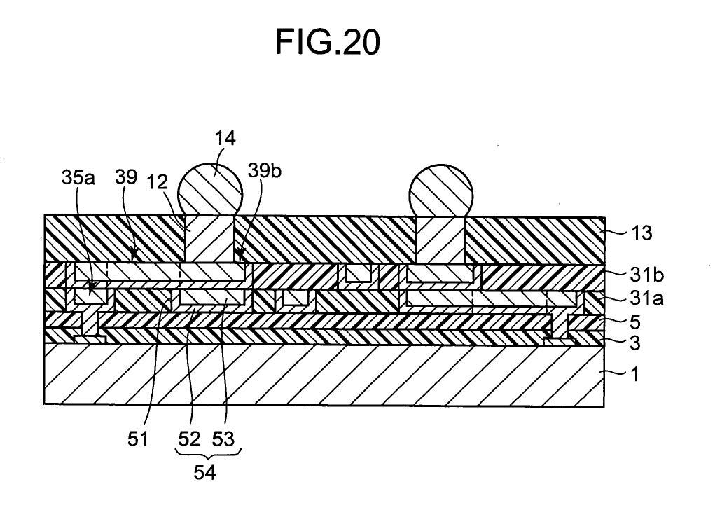

FIG. 20 is a sectional view of a semiconductor device as a third embodiment of the present invention. The semiconductor device differs from the semiconductor device as shown in FIG. 12 in the fact that an opening 51 is provided in the first upper layer insulating film 31a which is the region corresponding to the connection pad section 39b for the second wiring 39 where the columnar electrode 12 is formed, and that a dummy connection pad section 54 is provided in an island shape in the opening 51. The dummy connection pad section 54 consists of a dummy underlying metal layer 52 and a dummy upper metal layer 53 which is laminated on the dummy underlying metal layer 52.

In the semiconductor device, a dummy connection pad section 54 is provided in an island shape in the opening 51 of the first upper layer insulating film 31a which is below the connection pad section 39b for the second wiring 39 below the columnar electrodes 12. Therefore, seat portions of all columnar electrodes 12 can be aligned in height. Since the method of manufacturing a semiconductor device can be readily understood from the above-described manufacturing method of the second embodiment, the description thereof will be omitted.

Various embodiments and changes may be made thereunto without departing from the broad spirit and scope of the invention. The above-described embodiments are intended to illustrate the present invention, not to limit the scope of the present invention. The scope of the present invention is shown by the attached claims rather than the embodiments. Various modifications made within the meaning of an equivalent of the claims of the invention and within the claims are to be regarded to be in the scope of the present invention.

This application is based on Japanese Patent Application No. 2007-050001 filed on Feb. 28, 2007 and including specification, claims, drawings and summary. The disclosure of the above Japanese Patent Application is incorporated herein by reference in its entirety.

What is claimed is:

1. A semiconductor device comprising:
a semiconductor substrate which has a plurality of connection pads on a top surface thereof;
an insulating film which is provided on the semiconductor substrate and which has a plurality of openings formed at portions corresponding to the connection pads;
a plurality of re-wirings each of which is provided to be connected to one of the connection pads via one of the openings of the insulating film;
a re-wiring upper layer insulating film which is filled between the re-wirings on a top surface of the insulating film, and which is provided such that a top surface thereof is as high as or higher than a top surface of the re-wirings; and
a plurality of columnar electrodes each of which is provided to be connected to a top surface-side connection pad section of each of the re-wirings.

2. The semiconductor device according to claim 1; wherein
each of the re-wirings includes an underlying metal layer formed on the top surface of the insulating film and on the side surfaces of the re-wiring upper layer insulating film, and upper metal layers formed on the underlying metal layer.

3. A semiconductor device comprising:
a semiconductor substrate which has a plurality of connection pads on a top surface thereof;
an insulating film which is provided on the semiconductor substrate and which has a plurality of openings formed at portions corresponding to the connection pads;
a plurality of bottom surface-side wirings each of which is provided to be connected to one of the connection pads via one of the openings of the insulating film;
a bottom surface-side upper layer insulating film which is filled between the bottom surface-side wirings on a top surface of the insulating film,
a plurality of re-wirings each of which is provided to be connected to a bottom surface-side connection pad section of each of the bottom surface-side wirings;
a re-wiring upper layer insulating film which is filled between the re-wirings on a top surface of the bottom surface-side upper layer insulating film and on top surfaces of the bottom surface-side wirings, and which is provided such that a top surface thereof is as high as or higher than a top surface of the re-wirings; and
a plurality of columnar electrodes each of which is provided to connect to a top surface-side connection pad section of each of the re-wirings.

4. The semiconductor device according to claim 3, wherein
each of the re-wirings includes an underlying metal layer formed either on the top surface of the bottom surface-side upper layer insulating film or on the top surfaces of the bottom surface-side wirings and on side surfaces of the re-wiring upper layer insulating film, and upper metal layers formed on the underlying metal layer.

5. The semiconductor device according to claim 3, wherein
at least one of the bottom surface-side wirings includes only the bottom surface-side connection pad section which is connected to one of the connection pads.

6. The semiconductor device according to claim 3, wherein
at least one of the bottom surface-side wirings includes only the bottom surface-side connection pad section which is connected to one of the connection pads, and
a dummy connection pad section is provided in an island shape below the top surface-side connection pad section of one of the re-wirings which is connected to the at least one bottom surface-side wirings.

7. The semiconductor device according to claim 3, wherein
at least one of the re-wirings includes only the top surface-side connection pad section which is connected to the bottom surface-side connection pad section of one of the bottom surface-side wirings.

8. The semiconductor device according to claim 1, wherein
a passivation film is provided around the columnar electrodes.

9. The semiconductor device according to claim 8, wherein
a solder ball is provided on each of the columnar electrodes.

10. The semiconductor device according to claim 3, wherein
a passivation film is provided around the columnar electrodes.

11. The semiconductor device according to claim 10, wherein
a solder ball is provided on each of the columnar electrodes.

12. A method of manufacturing a semiconductor device comprising:
forming, on a semiconductor substrate which has a plurality of connection pads on a top surface thereof, an insulating film having a plurality of openings at portions corresponding to the connection pads;
forming, on a top surface of the insulating film, a re-wiring upper layer insulating film having a plurality of top surface-side openings each of which communicates with each of the openings;
forming, in the top surface-side openings of the re-wiring upper layer insulating film, a metal layer to serve as a plurality of re-wirings such that a top surface thereof is as high as or lower than a top surface of the re-wiring upper layer insulating film;
forming, on the top surface of the metal layer, a plating resist film for columnar electrode formation which has a plurality of openings for columnar electrode at portions to serve as top surface-side connection pad sections of the re-wirings;
forming a plurality of columnar electrodes on top surfaces of the top surface-side connection pad sections of the re-wirings in the openings of the plating resist film for columnar electrode formation;
delaminating the plating resist film for columnar electrode formation; and
forming the re-wirings by etching the metal layer to remove at least portions which are formed on the re-wiring upper layer insulating film.

13. The method of manufacturing a semiconductor device according to claim 12, wherein
forming the metal layer to serve as the re-wirings includes:
forming an underlying metal layer on the top surface of the re-wiring upper layer insulating film, on side surfaces of the re-wiring upper layer insulating film and the top surface of the insulating film in the top surface-side openings, and on side surfaces of the insulating film and top surfaces of the connection pads in the openings;
forming a plating resist film for forming re-wiring at least at portions corresponding to the re-wiring upper layer insulating film on a top surface of the underlying metal layer; and
forming upper metal layers on side surfaces and on the top surface of the underlying metal layer in the top surface-side openings of the re-wiring upper layer insulating film, by carrying out electrolytic plating using the underlying metal layer as a plating current path, such that top surfaces thereof is as high as or lower than the top surface of the re-wiring upper layer insulating film.

14. A method of manufacturing a semiconductor device comprising:
forming, on a semiconductor substrate which has a plurality of connection pads on a top surface thereof, an insulating film having a plurality of openings at portions corresponding to the connection pads;
forming, on a top surface of the insulating film, a bottom surface-side upper layer insulating film having a plurality of bottom surface-side openings each of which communicates with each of the openings;
forming, in the bottom surface-side openings of the bottom surface-side upper layer insulating film, a plurality of bottom surface-side wirings such that a top surface thereof is as high as or lower than a top surface of the bottom surface-side upper layer insulating film;
forming, on the top surface of the bottom surface-side upper layer insulating film and on top surfaces of the bottom surface-side wirings, a re-wiring upper layer insulating film having a plurality of top surface-side openings each of which communicates with each of the bottom surface-side openings;
forming, in the top surface-side openings of the re-wiring upper layer insulating film, a metal layer to serve as a plurality of re-wirings such that a top surface thereof is as high as or lower than a top surface of the re-wiring upper layer insulating film;
forming, on the top surface of the metal layer, a plating resist film for columnar electrode formation which has a plurality of openings for columnar electrode at portions to serve as top surface-side connection pad sections of the re-wirings;
forming a plurality of columnar electrodes on top surfaces of the top surface-side connection pad sections of the re-wirings in the openings of the plating resist film for columnar electrode formation;
delaminating the plating resist film for columnar electrode formation; and
forming the re-wirings by etching the metal layer to remove at least portions which are formed on the re-wiring upper layer insulating film.

15. The method of manufacturing a semiconductor device according to claim 14, wherein
forming the metal layer to serve as the re-wirings includes;
forming an underlying metal layer on the top surface of the re-wiring upper layer insulating film, on side surfaces of the re-wiring upper layer insulating film in the top surface-side openings, on the top surface of the bottom surface-side upper layer insulating film and on the top surfaces of the bottom surface-side wirings:
forming a plating resist film for forming re-wiring at least at portions corresponding to the re-wiring upper layer insulating film on a top surface of the underlying metal layer; and
forming upper metal layers on side surfaces and on the top surface of the underlying metal layer in the top surface-side openings of the re-wiring upper layer insulating film, by carrying out electrolytic plating using the underlying metal layer as a plating current path, such that top surfaces thereof is as high as or lower than the top surface of the re-wiring upper layer insulating film.

16. The method of manufacturing a semiconductor device according to claim 14, wherein
forming the bottom surface-side wirings includes:
forming at least one of the bottom surface-side wirings such that they include only the bottom surface-side connection pad section which is connected to one of the connection pads.

17. The method of manufacturing a semiconductor device according to claim 16, wherein
forming the bottom surface-side wirings includes:
forming at least one of the bottom surface-side wirings such that they include only the bottom surface-side connection pad section which is connected to one of the connection pads, and
forming a dummy connection pad section in an island shape below the top surface-side connection pad section of at least one of the re-wirings which is connected to the at least one bottom surface-side wirings.

18. The method of manufacturing a semiconductor device according to claim 14, wherein
forming the re-wirings includes:
forming at least one of the re-wirings such that they include only the top surface-side connection pad section which is connected to the bottom surface-side connection pad section of one of the bottom surface-side wirings.

19. The method of manufacturing a semiconductor device according to claim 12, further comprising:
forming a passivation film around the columnar electrodes.

20. The method of manufacturing a semiconductor device according to claim 19, further comprising:
forming a solder ball on each of the columnar electrodes.

21. The method of manufacturing a semiconductor device according to claim 14, further comprising:
forming a passivation film around the columnar electrodes.

22. The method of manufacturing a semiconductor device according to claim 21, further comprising:
forming a solder ball on each of the columnar electrodes.

23. A method of manufacturing a semiconductor device comprising:
forming, on a semiconductor substrate which has a plurality of connection pads on a top surface thereof, an insulating film having a plurality of openings at portions corresponding to the connection pads;
forming, on a top surface of the insulating film, a bottom surface-side upper layer insulating film having a plurality of bottom surface-side openings each of which communicates with each of the openings;
forming, in the bottom surface-side openings of the bottom surface-side upper layer insulating film, a plurality of bottom surface-side wirings such that a top surface thereof is as high as or lower than a top surface of the bottom surface-side upper layer insulating film;
forming, on the top surface of the bottom surface-side upper layer insulating film and on top surfaces of the bottom surface-side wirings, a re-wiring upper layer insulating film having a plurality of top surface-side openings each of which communicates with each of the bottom surface-side openings;
forming, in the top surface-side openings of the re-wiring upper layer insulating film, a metal layer to serve as a plurality of re-wirings such that a top surface thereof is as high as or lower than a top surface of the re-wiring upper layer insulating film;
forming, on the top surface of the metal layer, a plating resist film for columnar electrode formation made of a dry film which has a plurality of openings for columnar electrodes at portions to serve as top surface-side connection pad sections of the re-wirings;
forming a plurality of columnar electrodes on top surfaces of the top surface-side connection pad sections of the re-wirings in the openings of the plating resist film for columnar electrode formation;
delaminating the plating resist film for columnar electrode formation; and
forming the re-wirings by etching the metal layer to remove at least portions which are formed on the re-wiring upper layer insulating film.

24. The method of manufacturing a semiconductor device according to claim 23, wherein the plating resist film for columnar electrode formation is of a negative type.
